(19) United States
(12) Patent Application Publication
(10) Pub. No.: US 2023/0297336 A1
(43) Pub. Date: Sep. 21, 2023

(54) MULTIPLE MULTIPLICATION ARRAYS

(71) Applicant: Arm Limited, Cambridge (GB)

(72) Inventors: Nicholas Andrew PFISTER, Austin, TX (US); David Raymond LUTZ, Austin, TX (US); Harsha VALSARAJU, Austin, TX (US)

(21) Appl. No.: 17/698,166

(22) Filed: Mar. 18, 2022

(51) Int. Cl. G06F 7/53; G06F 7/527; H03K 19/017; H03K 19/20

(52) U.S. Cl. CPC G06F 7/5324; G06F 7/5277; H03K 19/01728; H03K 19/20

(57) ABSTRACT

A data processing apparatus is provided. An A×B multiplier array has a group of logic gates clocked by a first clock signal, where A and B are both integers. A C×D multiplier array, separate from the A×B multiplier array, has second group of logic gates clocked by a second clock signal, where C and D are both integers. Addition circuitry performs an addition operation between a first at least partial product produced by the A×B multiplier array and a second at least partial product produced by the C×D multiplier array.

### TECHNICAL FIELD

The present disclosure relates to data processing.

### DESCRIPTION

In a data processing apparatus, multiplication operations can be processor and power intensive. In addition, they are often large, which itself leads to an increase in power consumption for the data processing apparatus. It is desirable to implement multiplication circuits in such a way that they are small and such that they are able to operate with a small amount of power.

### SUMMARY

Viewed from a first example configuration, there is provided a data processing apparatus comprising: an A×B multiplier array comprising a first plurality of logic gates clocked by a first clock signal, where A and B are both integers; a C×D multiplier array, separate from the A×B multiplier array, comprising a second plurality of logic gates clocked by a second clock signal, where C and D are both integers; and addition circuitry configured to perform an addition operation between a first at least partial product produced by the A×B multiplier array and a second at least partial product produced by the C×D multiplier array.

Viewed from a second example configuration, there is provided a data processing method comprising: providing a first clock signal to an A×B multiplier array comprising a first plurality of logic gates, where A and B are both integers; providing a second clock signal to a C×D multiplier array, separate from the A×B multiplier array, comprising a second plurality of logic gates, where C and D are both integers; and performing an addition operation between a first at least partial product produced by the A×B multiplier array and a second at least partial product produced by the C×D multiplier array.

Viewed from a third example configuration, there is provided a non-transitory computer-readable medium to store computer-readable code for fabrication of a data processing apparatus comprising: an A×B multiplier array comprising a first plurality of logic gates clocked by a first clock signal, where A and B are both integers; a C×D multiplier array, separate from the A×B multiplier array, comprising a second plurality of logic gates clocked by a second clock signal, where C and D are both integers; and addition circuitry configured to perform an addition operation between a first at least partial product produced by the A×B multiplier array and a second at least partial product produced by the C×D multiplier array.

### BRIEF DESCRIPTION OF THE DRAWINGS

The present invention will be described further, by way of example only, with reference to embodiments thereof as illustrated in the accompanying drawings, in which:

FIG. 1 schematically illustrates an example of a data processing apparatus;

FIG. 2 illustrates individual bit operations in accordance with some examples;

FIG. 3A illustrates a data processing apparatus containing four multiplier arrays;

FIG. 3B shows the final products produced by each of the multiplier arrays;

FIG. 4A shows a data processing apparatus in accordance with some examples of the present technique;

FIG. 4B illustrates how the control of the first and second clock signals can be used to control the multiplier arrays;

FIG. 5A illustrates a configuration that uses three multiplier arrays;

FIG. 5B illustrates a variant configuration in which the shapes of the second multiplier array and the third multiplier array have been rotated;

FIG. 6 illustrates a configuration containing a large number of multiplier arrays;

FIG. 7 shows a logical arrangement of the multiplier arrays;

FIG. 8 shows a configuration of how, for instance, the multiplier arrays shown in FIG. 7 might be implemented; and

FIG. 9 illustrates a variant in which a single addition circuit is provided for all of the addition operations.

### DESCRIPTION OF EXAMPLE EMBODIMENTS

Before discussing the embodiments with reference to the accompanying figures, the following description of embodiments is provided.

In accordance with one example configuration there is provided a data processing apparatus comprising: an A×B multiplier array comprising a first plurality of logic gates clocked by a first clock signal, where A and B are both integers; a C×D multiplier array, separate from the A×B multiplier array, comprising a second plurality of logic gates clocked by a second clock signal, where C and D are both integers; storage circuitry to simultaneously store a first at least partial product produced by the A×B multiplier array and a second at least partial product produced by the C×D multiplier array; and addition circuitry to perform an addition operation on contents of the storage circuitry.

In the above examples, both an A×B multiplier array and a C×D multiplier array are provided. The A×B multiplier array comprises a set of logic gates (e.g. AND gates) that are arranged in order to produce the at least partial products for a multiplication of a first A bits of a first operand and B bits of a second operand. Similarly, the C×D multiplier array contains a different set of logic gates (e.g. AND gates that independent from the logic gates of the A×B multiplier array) and is able to perform a multiplication on C bits of a first operand and D bits of a second operand. The operands operated on by the A×B multiplier array and the C×D multiplier array could be completely different operands or could be the same operands, as will be discussed below. Each of the arrays receives a different clock signal. In this way, it is possible to effectively ‘freeze’ one of the arrays, preventing it from moving data around. This acts as an efficient way to enable or disable one of the circuits, since without the ‘tick’ of a clock signal, no output is produced by the relevant multiplier array and energy is not consumed as a result of switching. Furthermore, as opposed to a technique such as data gating (in which an enable/disable signal is asserted to the individual logic gates to indicate that they should or should not operate), this can be achieved without a further set of logic gates being added. This is important because although data gating might, for instance, help to reduce power consumption, it does so as the addition of a further set of logic gates—each of which will consume a small amount of power (e.g. due to leakage currents and so on). In these examples, the at least partial products produced by the A×B multiplier array and the C×D multiplier array can be simultaneously stored within the same storage circuitry and added together by the addition circuitry. Thus, it is possible for each of the multiplier arrays to be used in isolation or together in order to perform a multiplication operation. Consequently, circuit space is also saved as a consequence of not merely having a large number of independent multiplier arrays. Note that although the clock signal provided to each of the multiplier arrays is different (in at least some modes of operation), the clock signals could have the same source and could also have the same value (in some other modes of operation).

In some examples, in an A×B mode of operation, the first clock signal operates at a higher frequency than the second clock signal. A higher frequency clock signal produces the ‘tick’ signal at a higher rate than a lower frequency clock signal. Consequently, the speed at which data passes through transistors/logic gates of the A×B multiplier array is increased as compared to the C×D multiplier array.

In some examples, in the A×B mode of operation, the first clock signal is such that the contents of the storage circuitry on which the addition operation is performed by the addition operation includes the first at least partial product and excludes the second at least partial product. The clock signal provided to the A×B multiplier array is therefore sufficiently fast that when the addition operation is to be performed, the at least partial product(s) produced by the A×B multiplication will have completed. In contrast, the clock signal provided to the C×D multiplier array is so slow (or non-existent) such that no at least partial product(s) are produced. Consequently, the only addition to be performed by the addition circuitry is on the at least partial product(s) produced by the A×B multiplier array. Thus, in the A×B mode of operation, multiplication is performed on A bits of a first operand and B bits of a second operand, without any significant energy being consumed by the C×D multiplier array. It is therefore possible to perform an A×B multiplication without significant expenditure of energy on other circuits.

In some examples, in a C×D mode of operation, the second clock signal operates at a higher frequency than the first clock signal. A higher frequency clock signal produces the ‘tick’ signal at a higher rate than a lower frequency clock signal. Consequently, the speed at which data passes through transistors/logic gates of the C×D multiplier array is increased as compared to the A×B multiplier array.

In some examples, in the C×D mode of operation, the second clock signal is such that the contents of the storage circuitry on which the addition operation is performed by the addition operation excludes the first at least partial product and includes the second at least partial product. The clock signal provided to the C×D multiplier array is therefore sufficiently fast that when the addition operation is to be performed, the at least partial product(s) produced by the C×D multiplication will have completed. In contrast, the clock signal provided to the A×B multiplier array is so slow (or non-existent) such that no at least partial product(s) are produced. Consequently, the only addition to be performed by the addition circuitry is on the at least partial product(s) produced by the C×D multiplier array. Thus, in the C×D mode of operation, multiplication is performed on C bits of a first operand and D bits of a second operand, without any significant energy being consumed by the A×B multiplier array. It is therefore possible to perform a C×D multiplication without significant expenditure of energy on other circuits.

In some examples, in a combined mode of operation, the first clock signal and the second clock signal operate at frequencies such that the contents of the storage circuitry on which the addition operation is performed by the addition operation includes the first at least partial product and the second at least partial product. In this mode of operation, the at least partial products produced by each of the A×B multiplier and the C×D multiplier are added together as part of the addition operation due to the first clock signal and the second clock signal being comparable.

In some examples, in the combined mode of operation, the first clock signal and the second clock signal operate at a same frequency. In these examples, the first clock signal and the second clock signal could be the same signal (i.e. operating from a same source signal without the signal being modified differently for the A×B multiplier array or the C×D multiplier array).

In some examples, in the combined mode of operation, the A×B multiplier array and the C×D multiplier array cooperate to perform an M×N multiplication where M=A+C and N=B+D. The two multiplier arrays can therefore be ‘combined’ in order to perform a multiplication on larger operands than can be achieved individually on the A×B multiplier array or the C×D multiplier array. In particular, the M bits of a first operand can be split between the A×B multiplier array and the C×D multiplier array, together with the N bits of a second operand. By then operating each of the A×B multiplier array and the C×D multiplier array to produce at least partial products, and then combining the at least partial products in the addition operation, the result is the same as if a single M×N multiplier array had been used.

In some examples, in the combined mode of operation, A bits of a first operand are processed by the A×B multiplier array, B bits of a second operand are processed by the A×B multiplier array, C bits of the first operand are processed in the C×D multiplier array, and D bits of the second operand are processed in the C×D multiplier array. The two multiplier arrays are therefore ‘filled’ in order to effectively perform the M×N multiplication. Of course, it is also possible for a multiplication smaller than M×N to be performed using the same circuitry (e.g. a multiplication bigger than either of A×B or C×D, yet smaller than M×N) by padding bits in the M×N multiplication circuitry. However, this can result in wasted energy consumption as a consequence of some of the cells in the multiplication arrays being used to no useful effect. This can be alleviated by adding further multiplication arrays whose size more closely corresponds with the multiplications being performed.

In some examples, in the combined mode of operation, an upper A bits of a first operand and a lower B bits of a second operand are processed in the A×B multiplier array, and a lower C bits of the first operand and an upper D bits of the second operand are processed in the C×D multiplier array. With such a configuration, the resulting partial problems that are produced often fall within a smaller space than if the upper C bits of the first operand and lower D bits of the second operand are processed in the C×D multiplier array. This configuration therefore leads to a smaller storage circuitry being required in order to store the at least partial products that are produced by the multiplier arrays.

In some examples, the data processing apparatus comprises: an E×F multiplier array, separate from the A×B multiplier array and the C×D multiplier array, comprising a third plurality of logic gates clocked by a third clock signal, where E and F are both integers.

In some examples, the C×D multiplier array and the E×F multiplier array are multiplier array fragments and are non-square. In these examples, C and D differ from each other, and also E and F differ from each other, such that the multiplier arrays are non-square. These multiplier arrays can therefore be used to perform multiplications on differently sized operands.

In some examples, in the combined mode of operation, the A×B multiplier array and the C×D multiplier array and the E×F multiplier array cooperate to perform the M×N multiplication where M=A+C+E and N=B+D+F. Although the C×D multiplier array and the E×F multiplier array are non-square and can therefore be used to perform multiplications on differently sized operands, a more common use for the multiplier arrays is to expand the range of multiplication that can be achieved by another multiplier array (in this example, the A×B multiplier array). The A×B multiplier array can therefore be used to perform multiplication on one common size of operands. Meanwhile, larger multiplications can be performed (i.e. multiplication on larger operands can be achieved) by additionally using the C×D multiplier array and/or the E×F multiplier array. Bits of the two (large) operands are therefore split between the A×B multiplier array, the C×D multiplier array and the E×F multiplier array. The resulting at least partial products are then combined in the addition operation to produce a result of multiplying the two large operands.

In some examples, M and N are both 24. A 24×24 bit multiplication array is well-suited for performing multiplication on a single precision floating point number, whose mantissa is 23 bits (24 with the implicit whole number at the beginning).

In some examples, A and B are both 11. An 11×11 multiplication array is well-suited for performing multiplication on a half precision floating point number, whose mantissa is 10 bits (11 with the implicit whole number at the beginning). Consequently, such circuitry can efficiently perform multiplication for half precision floating point numbers. Meanwhile, by also using the C×D multiplier array, it is possible for larger multiplications to be performed. In some embodiments, the other multiplier arrays (C×D and/or E×F and/or others) are such that a 24×24 bit multiplication can also be efficiently performed, thereby enabling the efficient performance of both half and single precision floating point numbers. In one mode of operation, only the A×B multiplier array is used (by virtue of a higher frequency clock signal than is provided to the other multiplier arrays). In another mode of operation, the same clock signal can be provided to all of the multiplier arrays, and consequently, larger (e.g. 24×24 bit) multiplications can be performed. All of this can be achieved without having one 11×11 bit multiplier array and a separate 24×24 bit multiplier array, which would be wasteful of space. Similarly, this can be achieved without data gating, which would fail to reduce power consumption as much as the present techniques are able to achieve.

In some examples, the addition circuitry comprises first addition circuit for combining a first combination of at least partial products and a second addition circuit for combining a second combination of at least partial products in dependence on a selection signal. It may be that particular combinations of at least partial products are more efficiently added together. Consequently, different addition circuits can be provided to improve efficiency depending on the mode of operation in which the circuitry is operating. For example, if some multiplier arrays can be used to perform an integer dot product operation and other (or additional) multiplier arrays are also or alternatively used to perform floating-point related multiplications (e.g. of mantissas) then separate adder circuits could be provided to perform the integer dot product and to perform the floating point multiplication.

Particular embodiments will now be described with reference to the figures.

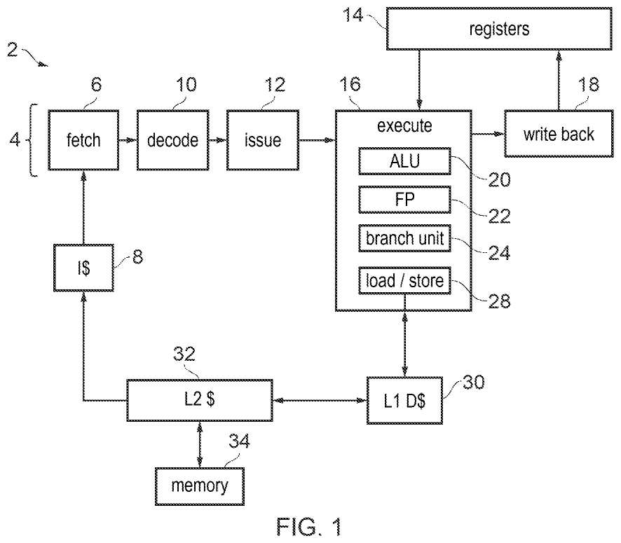

FIG. 1 schematically illustrates an example of a data processing apparatus 2. The data processing apparatus has a processing pipeline 4 which includes a number of pipeline stages. In this example, the pipeline stages include a fetch stage 6 for fetching instructions from an instruction cache 8; a decode stage 10 for decoding the fetch program instructions to generate micro-operations to be processed by remaining stages of the pipeline; an issue stage 12 for checking whether operands required for the micro-operations are available in a register file 14 and issuing micro-operations for execution once the required operands for a given micro-operation are available; an execute stage 16 for executing data processing operations corresponding to the micro-operations, by processing operands read from the register file 14 to generate result values; and a writeback stage 18 for writing the results of the processing back to the register file 14. It will be appreciated that this is merely one example of possible pipeline architecture, and other systems may have additional stages or a different configuration of stages. For example in an out-of-order processor an additional register renaming stage could be included for mapping architectural registers specified by program instructions or micro-operations to physical register specifiers identifying physical registers in the register file 14.

The execute stage 16 includes a number of processing units, for executing different classes of processing operation. For example the execution units may include an arithmetic/logic unit (ALU) 20 for performing arithmetic or logical operations; a floating-point unit (FPU) 22 for performing operations on floating-point values, a branch unit 24 for evaluating the outcome of branch operations and adjusting the program counter which represents the current point of execution accordingly; and a load/store unit 28 for performing load/store operations to access data in a memory system 8, 30, 32, 34. In this example the memory system include a level one data cache 30, the level one instruction cache 8, a shared level two cache 32 and main system memory 34. It will be appreciated that this is just one example of a possible memory hierarchy and other arrangements of caches can be provided. The specific types of processing unit 20 to 28 shown in the execute stage 16 are just one example, and other implementations may have a different set of processing units or could include multiple instances of the same type of processing unit so that multiple micro-operations of the same type can be handled in parallel. It will be appreciated that FIG. 1 is merely a simplified representation of some components of a possible processor pipeline architecture, and the processor may include many other elements not illustrated for conciseness, such as branch prediction mechanisms or address translation or memory management mechanisms. In the example of FIG. 1, the claimed apparatus might form part of the ALU 20, the FPU 22, could be shared between them, or might form part of a different data processing apparatus such as a graphics processing unit (GPU).

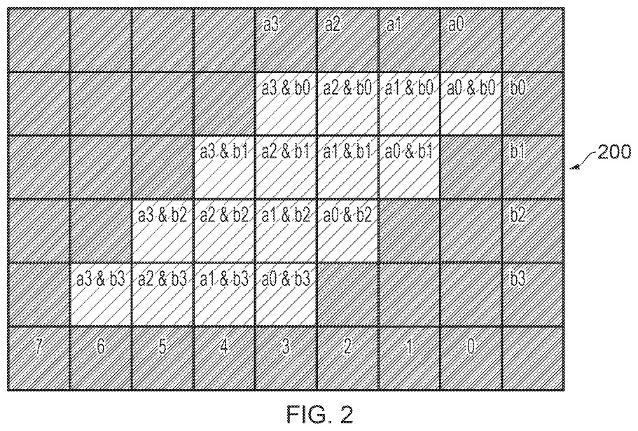

In a data processing apparatus, multiplication proceeds via a number of stages, which closely resembles the concept of ‘long multiplication’ similar to the process by which multiplication of numbers can be achieved by hand. For example, consider the multiplication of a first operand a[3:0] with a second operand b[3:0] using the 4×4 multiplier array 200 shown in FIG. 2. The first bit b[0] is multiplied by each of the four individual bits of a, the outputs of which form a first partial product. Then, the second bit b[1] is multiplied by each of the four individual bits of a, the outputs of which form a second partial product. Then the third bit b[2] is multiplied by each of the four individual bits of a, the outputs of which form a third partial product. Then the fourth bit b[3] is multiplied by each of the four individual bits of a, the outputs of which form a fourth partial product. Each successive partial product is left shifted by one place. Note that a multiplication between two bits can be achieved using the logical AND operation.

These partial products are then added together to form the final product, which is the result of the multiplication. Given the number of additions that occur, the addition can be performed efficiently by means of a carry-save-adder (CSA) network (which might operate on each logical column individually). CSA networks are particularly efficient when chained together since they output addition results as pairs of (carry, save) words (e.g. they output a redundant representation). A final non-carry-save adder is then provided in order to add the carry and save words together to produce a final product for the multiplication, which is equal to s[3:0]*b[3:0].

The CSA network may form part of the multiplier array 200 or may be separate.

As the skilled person will appreciate, although FIG. 2 illustrates individual bit operations, it is possible for each cell of the multiplier array 200 to operate on multiple (e.g. two) bits at once using a combination of logic gates. In this way, the multiplier array operates as a radix other than two.

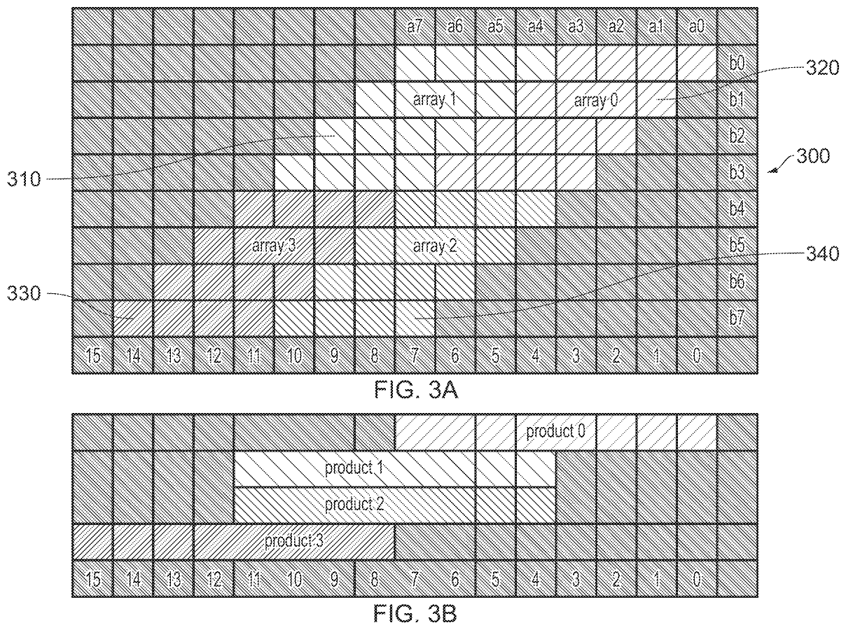

FIG. 3A illustrates a data processing apparatus 300 containing four 4×4 multiplier arrays 310, 320, 330, 340. By logically arranging the four multiplier arrays 310, 320, 330, 340 in the manner shown in FIG. 3, they collectively form the logical shape of a single 8×8 multiplier array and indeed, it is possible to use the multiplier arrays 310, 320, 330, 340 to perform 4×4, 8×4, 4×8, or 8×8 multiplications as desired. In particular, FIG. 3B shows the final products produced by each of the multiplier arrays 310, 320, 330, 340 (note that each product extends one bit further than indicated in FIG. 3A due to carry values on the most significant bits of the cells shown in FIG. 3A). The 12-bit product a[7:0]*b[3:0] is computed by adding products 0 and 1; the 12-bit product a[7:0]*b[7:4] is computed by adding products 2 and 3; and the 16-bit product a[7:0]*b[7:0] is computed by adding products 1, 2, 3, and 4. The addition of these products may also be accomplished using a CSA network followed by a non-CSA adder.

FIG. 3B shows four intermediate products produced by adding together four groups of partial products produced by the four multiplier arrays 310, 320, 330, 340. Those intermediate products are then added together to form the final product. However, it is also possible to achieve this in a single addition step by directly adding all of the partial products. For instance, all of the 16 partial products produced by the multiplier arrays 310, 320, 330, 340 might be added together in a single CSA network to provide the result of an 8×8 multiplication.

As explained above, different combinations of the multiplier arrays make it possible to perform multiplications of different sizes (e.g. where the operands have different numbers of bits). For the multiplier arrays that are unused, it is possible to insert ‘null’ data (e.g. with leading zeros in the case of a positive number) or to pad the input operands so that those multiplier circuits have no effect on the outcome. This, however, causes unnecessary processing to be performed in order to produce output bits that have no effect on the final result. This therefore increases power consumption of the data processing apparatus. Another possibility is to provide an ‘enable’ signal to each multiplier array so that multiplier arrays can be individually enabled or disabled. In particular, each AND operation illustrated in FIG. 1 could be treated as a double AND operation that additionally requires the enable signal to be asserted for the operation to proceed. For instance, the first operation could be expressed as a0 & b0 & enable. This, however, causes an increase in the number of logic gates in the data processing apparatus—each element in the multiplier array would effectively require two AND gates. Meanwhile, each logic gate uses circuit space and has an IR drop (as well as a leakage current) that consumes power. Therefore, although such a technique would prevent unnecessary processing, it will still increase power.

The present technique provides a different clock signal to different multiplier arrays 310, 320, 330, 340. Typically, each logic gate in such a data processing apparatus receives a clock signal in order to control the input and output of data. This prevents or inhibits incoming data to a logic gate from overwriting outgoing data of the logic gate. By using different clock signals for each of the multiplier arrays 310, 320, 330, 340, it is possible to ‘freeze’ some of the multiplier arrays. Meanwhile, since the logic gates already receive a clock signal, this using or freezing can be achieved without the addition of extra logic gates. Thus, processing of individual multiplier arrays can be inhibited (saving power) without a significant increase in the number of logic gates (which consume circuit space and power).

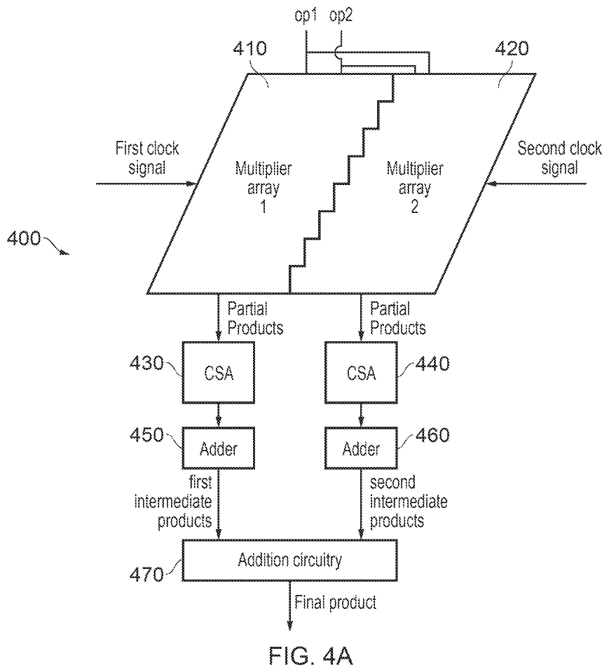

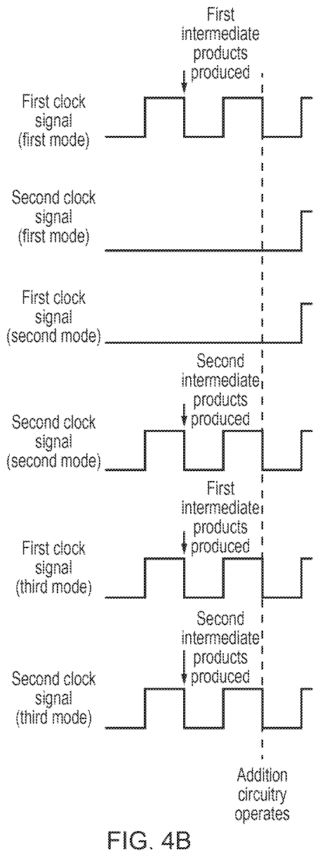

FIG. 4A shows a data processing apparatus 400 in accordance with some examples of the present technique. This might, for instance, be implemented as part of an arithmetic logic unit (ALU), floating point unit (FPU), or a graphical processing unit (GPU). A first multiplier array 410 and second multiplier array 420 are provided, which receive a first operand (op1) and a second operand (op2). In this example, the multiplier arrays 410, 420 are all different sizes meaning that they each operate on different numbers of bits of the operands op1 and op2. In addition, as will be discussed with reference to FIG. 4B, the first multiplier array 410 receives a first clock signal and the second multiplier array 420 receives a second clock signal. The two clock signals are different in the sense that their values can be made the same or different as desired.

Each of the multiplier arrays 410, 420 produces a set of partial products as previously described. These are passed to CSA networks 430, 440 and then to an (optional) regular adder 450, 460 to produce a set of intermediate products. These intermediate products are then added together by addition circuitry 470 (which may comprise further CSAs and non-CSAs). The regular adders 450, 460 are optional in the sense that the intermediate products could be kept in redundant representation and combined as part of the addition circuitry 470. Furthermore, as previously discussed, the CSAs are optional and all of the partial products could be directly added together by the addition circuitry 470.

By controlling the clock signal provided to each of the multiplier arrays 410, 420, the multiplier arrays 410, 420 can be individually rendered inert, thereby dramatically reducing their power consumption without significant increase to the circuit logic. In this way, the first multiplier array 410 can be used to perform a multiplication of one size, or the second multiplier array 420 can be used to perform a multiplication of a different size, or both multiplier arrays 410, 420 can be used together to perform a multiplication of a third (combined) size. Where only a single multiplier array 410, 420 is used, the addition circuitry 470 can be bypassed, since the intermediate products represent the final product.

FIG. 4B illustrates how the control of the first and second clock signals can be used to control the multiplier arrays 410, 420. In a first mode of operation in which only the first multiplier array 410 is to be used, the frequency of the first clock signal is significantly higher than that of the second clock signal provided to the second multiplier array 420. As a consequence, the first intermediate products are produced and passed to the addition circuitry 470 but no second intermediate products are produced. Consequently, there is no addition to be performed and the addition circuitry 470 can be bypassed (or alternatively, an addition can be performed by simply adding 0 to the first intermediate products). The reverse situation occurs in a second mode of operation in which the second multiplier array 420 is to be used in isolation. Here, the second clock signal is higher frequency than the first clock signal and so a second set of intermediate products are produced for a period when the addition circuitry 470 is to operate. In a third mode of operation, the first and second clock signals are equal or at least are such that at a time when the addition circuitry 470 is to operate, both a first set of intermediate products and a second set of intermediate products have been produced and can therefore be added together by the addition circuitry 470.

By virtue of this configuration, it is possible to activate only the smallest multiplier array(s) that are needed to complete a particular multiplication. Consequently, the entire set of multiplier arrays 410, 420 need not always be activated thereby saving power. At the same time, there is less chance of individual cells of the multiplier arrays 410, 420 going unused—which would be the case if only a single large multiplier array was provided. Additionally, the multiplier arrays 410, 420 can be made to cooperate and therefore circuit space (and power) is not wasted by having one multiplier array for each individual possible multiplication that might occur. In addition, by activating or deactivating the multiplier arrays 410, 420 by using clock signals, it is not necessary to add significant additional logic to the circuitry and so power consumption is not increased in order to implement a technique that can reduce power consumption.

In the above example, it is assumed that the addition circuitry 470 is clocked according to the higher frequency of either the first and second clock signals. Other techniques, that cause the addition circuitry to operate with whichever intermediate products have been provided, may also be possible.

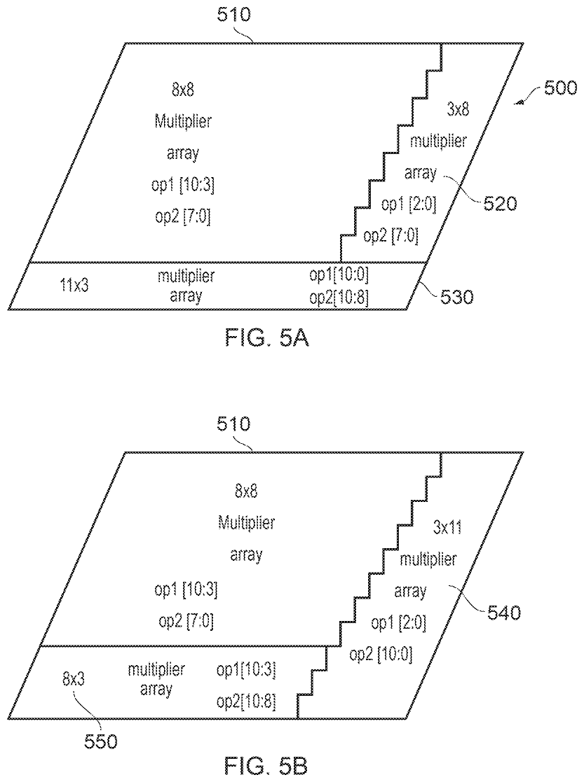

Other configurations of multiplier arrays are possible. FIG. 5A illustrates a configuration 500 that uses three multiplier arrays 510, 520, 530. The first multiplier array 510 is used to perform an 8×8 bit multiplication whereas the second multiplier array 520 is used to perform a 3×8 bit multiplication and the third multiplier array 530 is used to perform an 11×3 bit multiplication. The three multiplier arrays 510, 520, 530 can be combined to perform an 11×11 bit multiplication. In some embodiments, it may be determined that the likelihood of a 3×8 bit multiplication or an 11×3 bit multiplication being needed, individually, is very small. Consequently, both circuits could receive the same clock signal in order to perform the (more common) 11×11 bit multiplication. FIG. 5B illustrates a variant configuration in which the shapes of the second multiplier array 540 and the third multiplier array 550 have been rotated.

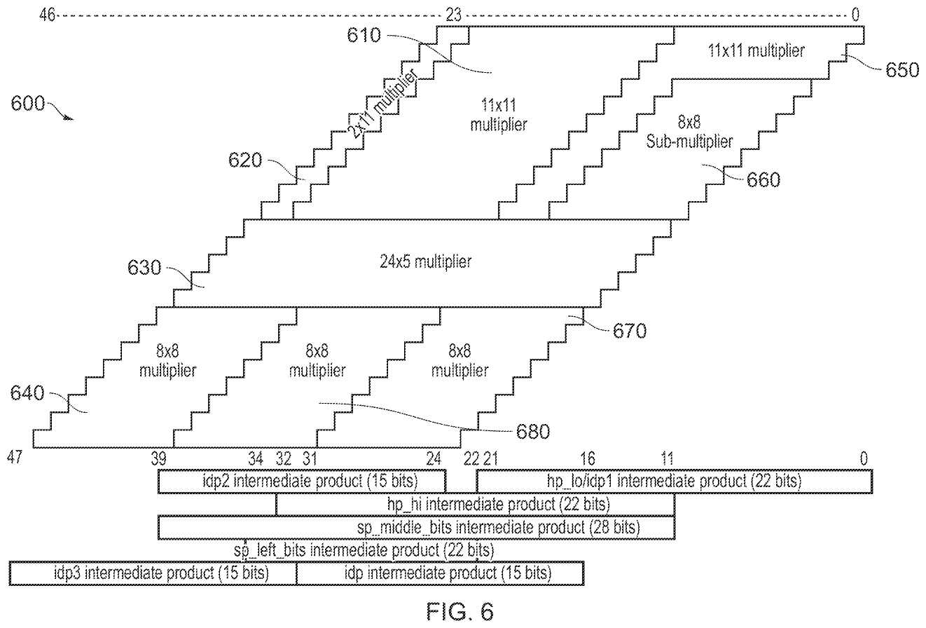

FIG. 6 illustrates a configuration 600 containing a large number of multiplier arrays 610, 620, 630, 640, 650, 660, 670, 680. This includes four 8×8 multipliers 640, 660, 670, 680 which can be used to perform four independent integer multiplications (or a single multiply-accumulate operation in which results of four 8×8 multiplications are added together—otherwise known as an integer dot product). There is also a pair of 11×11 multiplier arrays 610, 650. 11 bits corresponds with the number of bits in a half-precision floating point mantissa and hence is useful for performing multiplication for floating point numbers. One of these multiplier arrays 650 contains one of the 8×8 multiplier arrays 660 (which will be discussed in more detail below). In addition, multiplier array fragments 620, 630 are provided. Although these can be used to perform multiplications (of 2×11 bits and 24×5 bits respectively) they can, perhaps more importantly, be used in combination with each of the other multiplier arrays 610, 640, 650, 670, 680 to collectively form a 24×24 bit multiplier array. This corresponds with the number of bits in the mantissa of a single-precision floating point number and so is useful for floating point multiplication of single-precision floating point numbers.

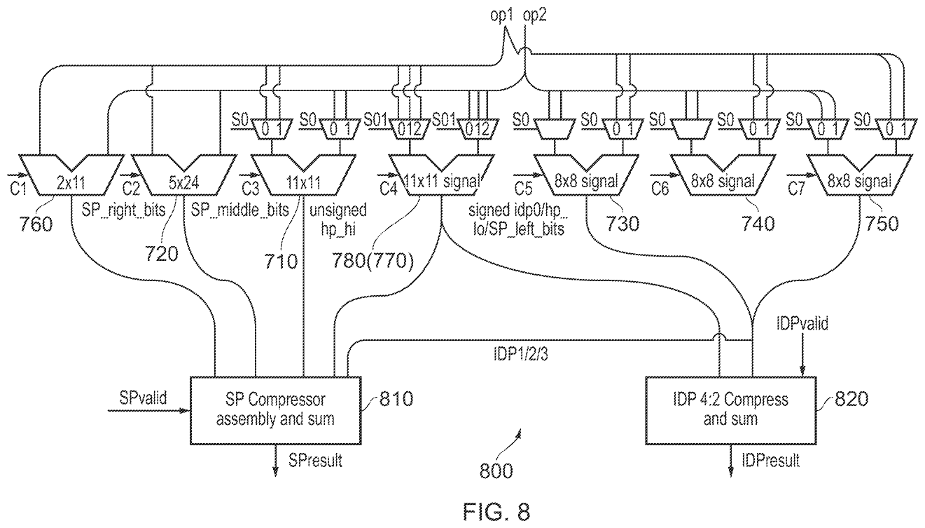

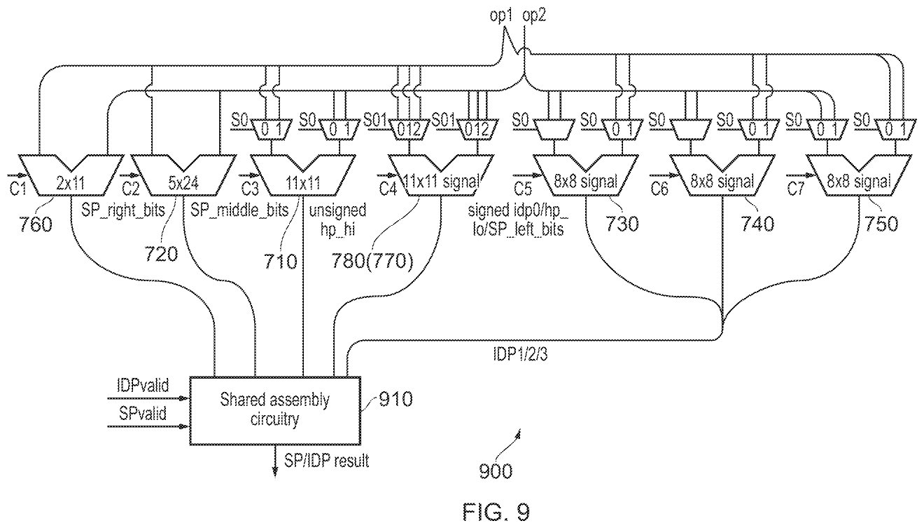

Thus, this circuitry can be used to efficiently perform multiplications on 8-bit integers to produce integer dot products (IDPs), single-precision floating point numbers, and half-precision floating point numbers. The actual arrangement of the circuits shown in FIG. 6 is indicative of the bits that are taken by each multiplier circuit when a single precision multiplication is being performed. That is to say that although three of the 8×8 multipliers 640, 670, 680 are shown as being aligned at the bottom of the structure, there is no need for them to operate on the same operand when performing independent 8×8 integer multiplications (e.g. as part of a multiply-accumulate operation). In these situations, as will be shown with respect to FIGS. 8 and 9, the inputs to each multiplier 640, 670, 680 can be selected arbitrarily.

One of the 8×8 multiplier arrays 660 is a sub-multipliers of one of the 11×11 bit multipliers 650. This provides an example of data-gating. In particular, this is a single 11×11 multiplier 650 that can be forced to act as an 8×8 multiplier array by means of a control signal to some of the cells in the 11×11 multiplier array 650. Although this could be less efficient when carried out for the entire set of multiplier arrays, when it is performed in such a limited manner (to cause an 11×11 multiplier array 650 to act as an 8×8 multiplier array 660) the number of extra logic gates required, and the number of logic gates that would actually be deactivated is relatively small and so the cost is also comparatively small.

The storage of the resulting intermediate products is shown at the bottom of FIG. 6. The storage in question keeps each of the bits in its correct logical position so that it maintains its correct value. As can be seen, this requires 5 ‘rows’ of 47 bits in order to avoid bits from the intermediate products from colliding.

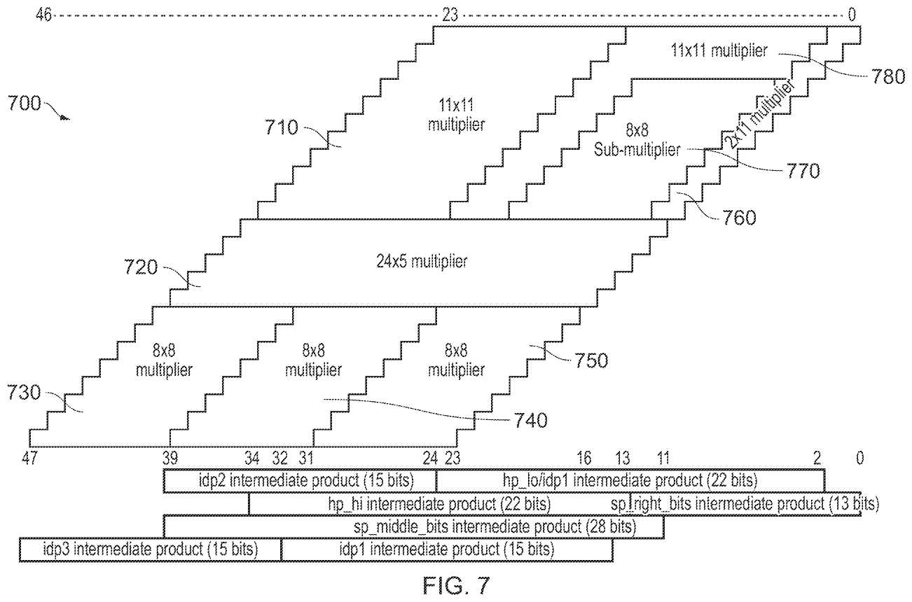

FIG. 7 shows a logical arrangement 700 of the multiplier arrays 710, 720, 730, 740, 750, 760, 770, 780 that are shown in FIG. 6. Once again, the arrangement 700 includes a pair of 11×11 multiplier arrays 710, 780, one of which can be configured to operate as an 8×8 multiplier array 770. There are also multiplier array fragments 780, 720 and a further three 8×8 multiplier arrays 730, 740, 750. In this configuration, however, one of the multiplier array fragments 760 has been shifted to the left. As a consequence of this, the storage required for the intermediate products (shown at the bottom of FIG. 7) can be reduced since now only four rows of 47 bits are required to store the intermediate products without collision in the columns.

FIG. 8 shows a configuration 800 of how, for instance, the multiplier arrays shown in FIG. 7 might be implemented. The two operands op1 and op2 (as 24-bit or 32-bit numbers) are received into each of the multiplier arrays 710, 720, 730, 740, 750, 760, 780(770). Each of the multiplier arrays receive a clock signal c1, . . . c7. A selection signal ‘s’ is used to indicate the data type to some of the multiplier arrays. In the case of the 11×11 array, a single bit s0 of this signal is used to indicate whether a single precision operation is being performed or whether a half precision multiplication is being performed. In the case of the other 11×11 multiplier array 780 that includes a sub-8×8 array 770, the two bits s01 of the selection signal are used to differentiate between a single precision multiplication, half precision multiplication, or 8×8 integer dot product operation. Meanwhile, the three 8×8 multiplier arrays 730, 740, 750 use one bit s1 of the selection signal to differentiate between a single precision multiplication and 8×8 integer dot product operations. The selection signal is used to determine which bits of the operands op1 and op2 are taken. Where a single precision multiplication is performed, the bits taken in will correspond to the alignment illustrated in FIG. 6 or 7 for example. In the case of the multiplier array 780 that contains the sub multiplier array 770, the selection signal is also used for the purpose of data gating, i.e. the selection signal is used to activate or deactivate some elements of the multiplier array.

The outputs are then compressed and combined (e.g. added) in separate adder circuits 810, 820. One addition circuit 820 is used for performing the integer dot product operation using the four 8×8 multipliers (36 bits are provided, in order to enable an 8×8 multiply-accumulate operation to proceed on four 8×8 multiplications). This circuitry 820 is activated via an IDPvalid signal that indicates whether an integer dot product is being performed. When signalled, the bits that are taken as inputs into at least some of the 8×8 multipliers are different to the bits taken in when the IDPvalid signal is not asserted. For instance, when asserted, one 8×8 multiplier circuit 730 might take the first 8 bits of op1 and the first 8 bits of op2 and a second 8×8 multiplier circuit 740 might take the second 8 bits of op1 and the second 8 bits of op2 and the third 8×8 multiplier circuit might take a third 8 bits of opt and a third 8 bits of op2 and so on. In this way, completely independent sets of bits can be provided to each of the 8×8 multipliers when a multiply-accumulate operation is being performed. Similarly for the 11×11 multipliers 710, 780 when half precision multiplication is performed. This same signal can be used to enable additional input flops that enable the op1 and op2 to be extended from 24-bit to 32-bit). A separate addition circuit 810 is used to perform other additions such as the single precision determination. This circuitry is enabled or disabled via an SPvalid signal that indicates whether a single point precision addition is being performed. Where half precision operations are being performed, neither of the addition circuits 810, 820 is required and the high and low bits output by the multiplexers 710, 780(770) can simply be merged. The addition circuits 810, 820 could therefore be bypassed, or they could be added to intermediate products of 0 via the addition circuit 810.

FIG. 9 illustrates a variant 900 in which a single addition circuit 910 is provided for all of the addition operations. Depending on whether IDPvalid or SPvalid is asserted, different intermediate products are combined to produce the desired output. Once again, for the formation of a half precision value (for instance), the addition circuit 910 could be bypassed. Alternatively, the half precision values from the multiplier arrays 710, 780(770) could be added to intermediate products of 0. This could be forced by, for instance, a third single HPvalid to indicate that a half precision value is desired.

This variant 900 uses less circuit space than the configuration 800 shown in FIG. 8. However, the variant 900 may not be able to take advantage of optimisations that might be possible when performing an integer dot product operation since the same circuitry is used for performing the multiplication for a single precision floating point value. Furthermore, the timing constraints for performing an integer dot product might be such that, without optimisation, the shared addition circuitry 910 might not be able to operate quickly enough in some architectures.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may be define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

Although illustrative embodiments of the invention have been described in detail herein with reference to the accompanying drawings, it is to be understood that the invention is not limited to those precise embodiments, and that various changes, additions and modifications can be effected therein by one skilled in the art without departing from the scope and spirit of the invention as defined by the appended claims. For example, various combinations of the features of the dependent claims could be made with the features of the independent claims without departing from the scope of the present invention.

Other aspects and features of the invention are set out in the following numbered clauses:
1. A data processing apparatus comprising:
   an A×B multiplier array comprising a first plurality of logic gates clocked by a first clock signal, where A and B are both integers;
   a C×D multiplier array, separate from the A×B multiplier array, comprising a second plurality of logic gates clocked by a second clock signal, where C and D are both integers; and
   addition circuitry configured to perform an addition operation between a first at least partial product produced by the A×B multiplier array and a second at least partial product produced by the C×D multiplier array.
2. The data processing apparatus according to clause 1, wherein
   in an A×B mode of operation, the first clock signal operates at a higher frequency than the second clock signal.
3. The data processing apparatus according to clause 2, wherein
   in the A×B mode of operation, the first clock signal is such that the contents of the storage circuitry on which the addition operation is performed by the addition operation includes the first at least partial product and excludes the second at least partial product.
4. The data processing apparatus according to any preceding clause, wherein
   in a C×D mode of operation, the second clock signal operates at a higher frequency than the first clock signal.
5. The data processing apparatus according to clause 4, wherein
   in the C×D mode of operation, the second clock signal is such that the contents of the storage circuitry on which the addition operation is performed by the addition operation excludes the first at least partial product and includes the at least second partial product.
6. The data processing apparatus according to any preceding clause, wherein
   in a combined mode of operation, the first clock signal and the second clock signal operate at frequencies such that the contents of the storage circuitry on which the addition operation is performed by the addition operation includes the first at least partial product and the second at least partial product.
7. The data processing apparatus according to clause 6, wherein
   in the combined mode of operation, the first clock signal and the second clock signal operate at a same frequency.
8. The data processing apparatus according to any one of clauses 6-7, wherein
   in the combined mode of operation, the A×B multiplier array and the C×D multiplier array cooperate to perform an M×N multiplication where M=A+C and N=B+D.
9. The data processing apparatus according to any one of clauses 6-8, wherein
   in the combined mode of operation, A bits of a first operand are processed by the A×B multiplier array, B bits of a second operand are processed by the A×B multiplier array, C bits of the first operand are processed in the C×D multiplier array, and D bits of the second operand are processed in the C×D multiplier array.
10. The data processing apparatus according to any one of clauses 6-9, wherein
   in the combined mode of operation, an upper A bits of a first operand and a lower B bits of a second operand are processed in the A×B multiplier array, and a lower C bits of the first operand and an upper D bits of the second operand are processed in the C×D multiplier array.
11. The data processing apparatus according to any one of clauses 6-10, comprising:
   an E×F multiplier array, separate from the A×B multiplier array and the C×D multiplier array, comprising a third plurality of logic gates clocked by a third clock signal, where E and F are both integers.
12. The data processing apparatus according to clause 11, wherein
   the C×D multiplier array and the E×F multiplier array are multiplier array fragments and are non-square.
13. The data processing apparatus according to any one of clauses 11-12, wherein
   in the combined mode of operation, the A×B multiplier array and the C×D multiplier array and the E×F multiplier array cooperate to perform the M×N multiplication where M=A+C+E and N=B+D+F.
14. The data processing apparatus according to clause 13, wherein
   M and N are both 24.
15. The data processing apparatus according to any preceding clause, wherein
   A and B are both 11.
16. The data processing apparatus according to any preceding clause, wherein
   the addition circuitry comprises first addition circuit for combining a first combination of at least partial products and a second addition circuit for combining a second combination of at least partial products in dependence on a selection signal.
17. A data processing method comprising:
   providing a first clock signal to an A×B multiplier array comprising a first plurality of logic gates, where A and B are both integers;
   providing a second clock signal to a C×D multiplier array, separate from the A×B multiplier array, comprising a second plurality of logic gates, where C and D are both integers; and
   performing an addition operation between a first at least partial product produced by the A×B multiplier array and a second at least partial product produced by the C×D multiplier array.
18. A non-transitory computer-readable medium to store computer-readable code for fabrication of a data processing apparatus comprising:
   an A×B multiplier array comprising a first plurality of logic gates clocked by a first clock signal, where A and B are both integers;
   a C×D multiplier array, separate from the A×B multiplier array, comprising a second plurality of logic gates clocked by a second clock signal, where C and D are both integers; and
   addition circuitry configured to perform an addition operation between a first at least partial product produced by the A×B multiplier array and a second at least partial product produced by the C×D multiplier array.

We claim:

1. A data processing apparatus comprising:
an A×B multiplier array comprising a first plurality of logic gates clocked by a first clock signal, where A and B are both integers;
a C×D multiplier array, separate from the A×B multiplier array, comprising a second plurality of logic gates clocked by a second clock signal, where C and D are both integers; and
addition circuitry configured to perform an addition operation between a first at least partial product produced by the A×B multiplier array and a second at least partial product produced by the C×D multiplier array.

2. The data processing apparatus according to claim 1, wherein
in an A×B mode of operation, the first clock signal operates at a higher frequency than the second clock signal.

3. The data processing apparatus according to claim 2, wherein
in the A×B mode of operation, the first clock signal is such that the contents of the storage circuitry on which the addition operation is performed by the addition operation includes the first at least partial product and excludes the second at least partial product.

4. The data processing apparatus according to claim 1, wherein
in a C×D mode of operation, the second clock signal operates at a higher frequency than the first clock signal.

5. The data processing apparatus according to claim 4, wherein
in the C×D mode of operation, the second clock signal is such that the contents of the storage circuitry on which the addition operation is performed by the addition operation excludes the first at least partial product and includes the at least second partial product.

6. The data processing apparatus according to claim 1, wherein
in a combined mode of operation, the first clock signal and the second clock signal operate at frequencies such that the contents of the storage circuitry on which the addition operation is performed by the addition operation includes the first at least partial product and the second at least partial product.

7. The data processing apparatus according to claim 6, wherein
in the combined mode of operation, the first clock signal and the second clock signal operate at a same frequency.

8. The data processing apparatus according to claim 6, wherein
in the combined mode of operation, the A×B multiplier array and the C×D multiplier array cooperate to perform an M×N multiplication where M=A+C and N=B+D.

9. The data processing apparatus according to claim 6, wherein
in the combined mode of operation, A bits of a first operand are processed by the A×B multiplier array, B bits of a second operand are processed by the A×B multiplier array, C bits of the first operand are processed in the C×D multiplier array, and D bits of the second operand are processed in the C×D multiplier array.

10. The data processing apparatus according to claim 6, wherein
in the combined mode of operation, an upper A bits of a first operand and a lower B bits of a second operand are processed in the A×B multiplier array, and a lower C bits of the first operand and an upper D bits of the second operand are processed in the C×D multiplier array.

11. The data processing apparatus according to claim 6, comprising:
an E×F multiplier array, separate from the A×B multiplier array and the C×D multiplier array, comprising a third plurality of logic gates clocked by a third clock signal, where E and F are both integers.

12. The data processing apparatus according to claim 11, wherein
the C×D multiplier array and the E×F multiplier array are multiplier array fragments and are non-square.

13. The data processing apparatus according to claim 11, wherein
in the combined mode of operation, the A×B multiplier array and the C×D multiplier array and the E×F multiplier array cooperate to perform the M×N multiplication where M=A+C+E and N=B+D+F.

14. The data processing apparatus according to claim 13, wherein
M and N are both 24.

15. The data processing apparatus according to claim 1, wherein
A and B are both 11.

16. The data processing apparatus according to claim 1, wherein
the addition circuitry comprises first addition circuit for combining a first combination of at least partial products and a second addition circuit for combining a second combination of at least partial products in dependence on a selection signal.

17. A data processing method comprising:
providing a first clock signal to an A×B multiplier array comprising a first plurality of logic gates, where A and B are both integers;
providing a second clock signal to a C×D multiplier array, separate from the A×B multiplier array, comprising a second plurality of logic gates, where C and D are both integers; and
performing an addition operation between a first at least partial product produced by the A×B multiplier array and a second at least partial product produced by the C×D multiplier array.

18. A non-transitory computer-readable medium to store computer-readable code for fabrication of a data processing apparatus comprising:
an A×B multiplier array comprising a first plurality of logic gates clocked by a first clock signal, where A and B are both integers;
a C×D multiplier array, separate from the A×B multiplier array, comprising a second plurality of logic gates clocked by a second clock signal, where C and D are both integers; and
addition circuitry configured to perform an addition operation between a first at least partial product produced by the A×B multiplier array and a second at least partial product produced by the C×D multiplier array.
